(19) United States
(12) Patent Application Publication
(10) Pub. No.: US 2009/0253261 A1
(43) Pub. Date: Oct. 8, 2009

(54) Silicon Wafer Having Through-Wafer Vias With A Predetermined Geometric Shape

(75) Inventors: Cormac MACNAMARA, Belfast (GB); Hugh J. GRIFFIN, Newtownabbey (GB); Robin WILSON, Belfast (GB)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: ICEMOS TECHNOLOGY LTD., Belfast (GB)

(21) Appl. No.: 12/485,096

(22) Filed: Jun. 16, 2009

Related U.S. Application Data
(62) Division of application No. 11/925,329, filed on Oct. 26, 2007.
Application No. 11/925,329 is a continuation-in-part of application No. 11/381,605, filed on May 4, 2006, now Pat. No. 7,553,764.
(60) Provisional application No. 60/677,510, filed on May 4, 2005.

(51) Int. Cl. H01L 21/768

(52) U.S. Cl. 438/667; 438/675; 438/48; 257/E21.597; 257/E21.585

(57) ABSTRACT

A method of manufacturing a semiconductor device includes providing a semiconductor substrate having first and second main surfaces opposite to each other, forming in the semiconductor substrate at least one trench of a predetermined geometric shape in the first main surface, lining the at least one trench with a dielectric material, filling the at least one trench with a conductive material, electrically connecting an electrical component to the conductive material of the at least one trench at the first main surface; and mounting a cap to the first main surface. The at least one trench extends to a first depth position D in the semiconductor substrate. The cap encloses at least a portion of the electrical component and the electrical connection between the electrical component and the conductive material.

### CROSS-REFERENCE TO RELATED APPLICATIONS

This application a divisional application of U.S. patent application Ser. No. 11/925,329, filed Oct. 26, 2007, entitled “Silicon Wafer Having Through-Wafer Vias with a Predetermined Geometic Shape;” which is a continuation-in-part of U.S. patent application Ser. No. 11/381,605, filed on May 4, 2006, entitled “Silicon Wafer Having Through-Wafer Vias;” which claims priority to U.S. Provisional Patent Application No. 60/677,510, filed on May 4, 2005, entitled “Silicon Wafer Having Through-Wafer Vias.”

### BACKGROUND OF THE INVENTION

Embodiments of the present invention relate to a semiconductor device and a method for manufacturing the semiconductor device, and more particularly, to a semiconductor device having through-wafer conductive vias with a predetermined geometric shape and a method of manufacturing a semiconductor device having through-wafer conductive vias.

Micro-electro-mechanical systems (MEMS) have led to the creation of a wide variety of small and fragile electrical components such as sensor technologies. Presently, these MEMS sensors are not typically compatible with standard integrated circuit (IC) packaging technologies because of their fragility. Some have considered going to wafer level packaging for such MEMS sensors, where the MEMS sensor is encapsulated as part of typical clean room processing by a bonding method such as using direct wafer bonding or anodic bonding of a glass or silicon protective cap over the MEMS sensor.

FIG. 1 shows one prior art method for mounting a MEMS sensor 90 to a silicon wafer or substrate 20 and enclosing the MEMS sensor 90 with a glass or silicon cap 80. As can be seen, an electrical lead 97 is run across the surface of the substrate 20 from the MEMS sensor or other electrical component 90. Routing the electrical connection through the cap 80 is not trivial and the interface 83 between the cap 80 and the electrical connector 97 often leads to an imperfect seal or problems with conductivity of the electrical connector.

It is desirable to provide a semiconductor device having through-wafer conductive vias for connecting to an electrical component such as a MEMS sensor from beneath the semiconductor substrate. It is also desirable to form the through-wafer conductive vias using the semiconductor substrate material itself so as to minimize a fill process.

### BRIEF SUMMARY OF THE INVENTION

Briefly stated, an embodiment of the present invention comprises a method of manufacturing a semiconductor device. To begin the process, a semiconductor substrate having first and second main surfaces opposite to each other is provided. At least one trench of a predetermined geometric shape is formed in the semiconductor substrate at the first main surface, the at least one trench extending to a first depth position D in the semiconductor substrate. The at least one trench is lined with a dielectric material and is filled with a conductive material. An electrical component is electrically connected to the conductive material of the at least one trench at the first main surface. A cap is mounted to the first main surface, the cap enclosing at least a portion of the electrical component and the electrical connection between the electrical component and the conductive material.

Another embodiment of the present invention comprises a method of manufacturing a semiconductor having a conductive via. To begin the process, a semiconductor substrate having first and second main surfaces opposite to each other is provided. At least one trench of a substantially rectangular shape is formed in the first main surface, the at least one trench extending to a first depth position D in the semiconductor substrate. The at least one trench is lined with a dielectric material and is filled with a conductive material. The second main surface is planarized to expose the conductive material surrounding the at least one trench, the at least one trench forming the conductive via.

Another embodiment of the present invention comprises a method of manufacturing a semiconductor device. To begin the process, a semiconductor substrate having first and second main surfaces opposite to each other is provided. At least one trench of a predetermined geographic shape is formed in the first main surface, the at least one trench extending to a first depth position D in the semiconductor substrate. The at least one trench is lined with a dielectric material and is filled with a conductive material.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a side elevational cross sectional view of a prior art encapsulated electrical component on a semiconductor substrate;

FIG. 2 is a partial sectional side elevational view of a semiconductor substrate used to form a semiconductor device in accordance with a first preferred embodiment of the present invention;

FIG. 3 is a partial sectional side elevational sectional view of the semiconductor substrate of FIG. 1 after a trenching step of a preferred embodiment of the invention;

FIG. 3A is a partial sectional side elevational sectional view of the semiconductor substrate of FIG. 1 after a trenching step of another preferred embodiment of the invention;

FIG. 4 is a partial sectional top plan view of a first preferred embodiment of the semiconductor substrate of FIG. 3;

FIG. 4A is a partial sectional top plan view of a second preferred embodiment of the semiconductor substrate of FIG. 3A;

FIG. 4B is a partial sectional top plan view of a third preferred embodiment of the semiconductor substrate of FIG. 3;

FIG. 4C is a partial sectional top plan view of a fourth preferred embodiment of the semiconductor substrate of FIG. 3;

FIG. 5 is a partial sectional side elevational view of the semiconductor substrate of FIG. 3 after a dielectric lining step;

FIG. 6 is a partial sectional side elevational view of the semiconductor substrate of FIG. 5 after a trench filling step;

FIG. 7 is a partial sectional side elevational view of the semiconductor substrate of FIG. 6 after planarizing a first side;

FIG. 8 is a partial sectional side elevational view of the semiconductor of FIG. 7 after planarizing a second side;

FIG. 9 is a partial sectional side elevational view of a formed semiconductor device in accordance with the first preferred embodiment;

FIG. 10 is a partial sectional top plan view of a semiconductor substrate having a trench defining a perimeter boundary in accordance with a fifth preferred embodiment of the present invention;

FIG. 11 is a partial sectional side elevational view of the semiconductor substrate of FIG. 10;

FIG. 12 is a partial sectional side elevational view of the semiconductor substrate of FIG. 11 after trench lining and filling;

FIG. 13 is a partial sectional side elevational view of the semiconductor substrate of FIG. 12 after planarizing a first surface; and

FIG. 14 is a partial sectional side elevational view of the semiconductor substrate of FIG. 13 after planarizing a second surface and metallizing conductive vias.

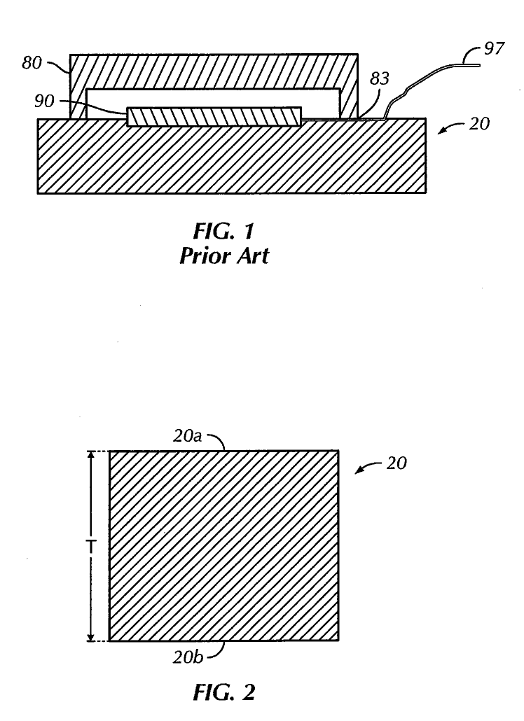

### DETAILED DESCRIPTION OF THE INVENTION

Certain terminology is used in the following description for convenience only and is not limiting. The words “right”, “left”, “lower”, and “upper” designate directions in the drawings to which reference is made. The words “inwardly” and “outwardly” refer direction toward and away from, respectively, the geometric center of the object described and designated parts thereof. The terminology includes the words above specifically mentioned, derivatives thereof and words of similar import. Additionally, the word “a” as used in the claims and in the corresponding portion of the specification, means “at least one.”

As used herein, reference to conductivity is for convenience only. However, those skilled in the art known that a P-type conductivity can be switched with an N-type conductivity and that the device would still function correctly. Therefore, where used herein, reference to N or P can also mean that either N or P and that P and N can be substituted therefor.

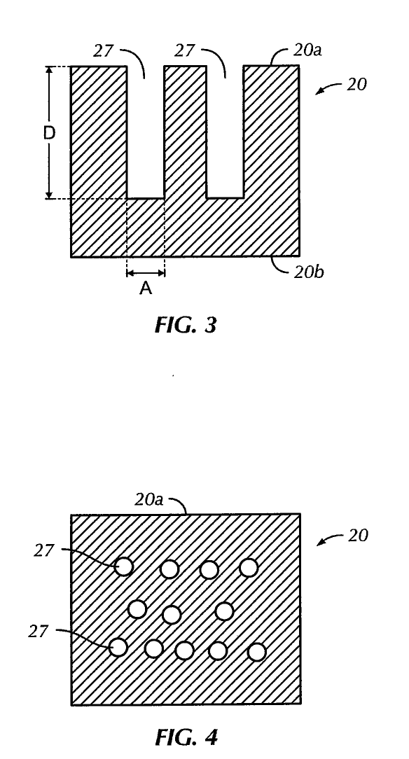

FIGS. 2-9 generally show a process of manufacturing a semiconductor device in accordance with preferred embodiments of the present invention.

Referring to FIG. 2, there is shown an elevational view of a semiconductor substrate or wafer 20. The semiconductor substrate 20 can be undoped, lightly doped or heavily doped if desired. Preferably, the semiconductor substrate 20 is heavily doped. The semiconductor substrate 20 has a first main surface 20a, a second main surface 20b and a thickness T.

Referring to FIG. 3, using techniques known in the art, the first main surface 20a of the semiconductor substrate 20 is etched to a first depth position D, but preferably, not all of the way through the semiconductor substrate 20. The etching process creates a trench 27 generally having a width A in the semiconductor substrate 20. Width A also represents the cross-sectional length of the trench 27. The etching process can be a chemical etch, a plasma etch, a Reactive Ion Etch (RIE), an inductively coupled plasma deep reactive ion etching (ICP DRIE) and the like. The trench 27 can also be formed utilizing micro-electro-mechanical systems (MEMS) technology to “machine” the semiconductor substrate 20. A plurality of trenches 27 may be formed in the semiconductor substrate 20 at spaced locations in a desired pattern depending on how many electrical connections are desired for a particular electrical component 90. Also, in the embodiment of FIG. 3A, a single trench 27 with width A is etched in the semiconductor substrate 20.

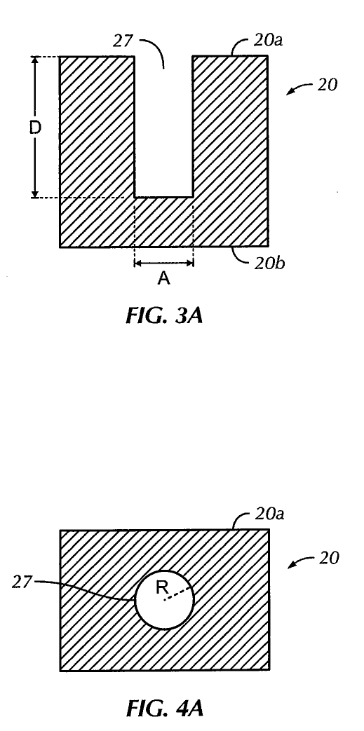

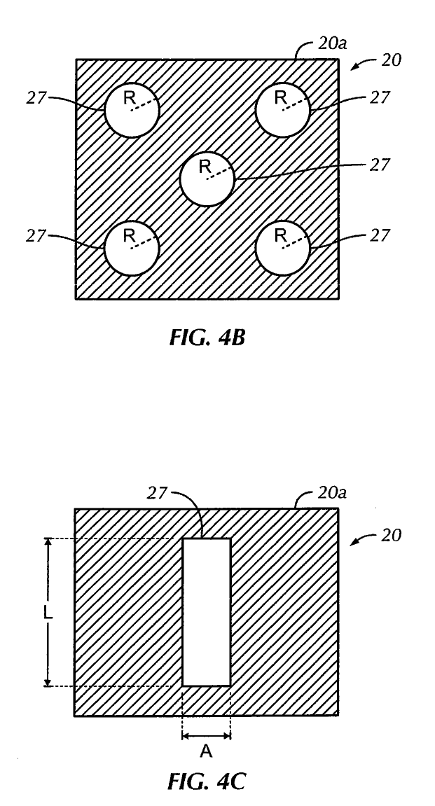

FIG. 4 shows a partial sectional top plan view of a first preferred embodiment of the semiconductor substrate 20 after a plurality of circular trenches 27 have been formed therein. The trenches 27 can be etched in a plurality of shapes such as circular (annular), triangular, rectangular, elliptical, polygonal or may be any non-geometric or geometric and symmetric or asymmetric shape. The plurality of shapes may also be etched at a plurality of widths A. For circular shapes, the width A is the diameter of the circle and therefore A is twice the radius R of the circle. FIG. 4A shows a partial sectional top plan view of a second preferred embodiment of the semiconductor substrate 20 after one circular trench 27 of a radius R equal to 39 micrometers (μm) has been formed therein. FIG. 4B shows a partial sectional top plan view of a third preferred embodiment of the semiconductor substrate 20 after five circular trenches 27 each of a radius R equal to 17 μm have been formed therein. For those shapes that require dimensions in addition to width A, the additional dimensions may vary among the same shapes. FIG. 4C shows a partial sectional top plan view of a fourth preferred embodiment of the semiconductor substrate 20 after a rectangular trench 27 of a length L equal to 240 μm and a width A equal to 20 μm has been formed therein. Given the orientation of the rectangular trench 27 in FIG. 4C, the width A is also the cross-section.

The time required to etch the trenches 27 of FIGS. 3 and 3A is an important commercial parameter in the manufacture of semiconductors having through-wafer conductive vias. The amount of time required to etch the trench 27 is directly proportional to the cost of manufacture of the semiconductor device that has the through-wafer conductive via. Therefore, the shorter the amount of time required to etch the trench 27, the lower the manufacturing cost of the semiconductor containing the through-wafer conductive via. This presents a challenge in the manufacture of semiconductors having through-wafer conductive vias in that for low resistance vias, for example vias with a resistance of about 1 Ohm (ÿ), the cross-sectional area of the via must be relatively large. For a circular shaped trench 27 like that of FIG. 4A and FIG. 4B, the etch rate by ICP DRIE is dependent on the cross-sectional area (ÿ×R² where R equals A/2), the depth position D and also on the number of circular trenches 27. The cross-sectional area of the single circular trench 27 of FIG. 4A is approximately 4800 μm². The total cross-sectional area of the five circular trenches 27 of FIG. 4B is approximately 17,300 μm². For a depth position of D equal to 400 μm, the etch time for the single circular trench 27 of FIG. 4A is approximately 250 minutes and the etch time for the five circular trenches 27 of FIG. 4B is approximately 270 minutes. For a rectangular shaped trench 27 like that of FIG. 4C, the etch rate by ICP DRIE is dependent on the length L and the width A (a cross-sectional area of the rectangular trench 27), the depth position D and also the number of rectangular trenches 27. The cross-sectional area of the singular rectangular shaped trench 27 of FIG. 4C is 4800 μm². For the same depth position D equal to 400 μm, the etch time for the single rectangular shaped trench 27 of FIG. 4C is approximately 230 minutes. As the etch times for the trenches 27 of FIGS. 4A and 4C indicate, although both shapes involve the same cross-sectional area, narrow holes etch slower than wide holes. In ICP DRIE and other reactive etching processes, the etching time difference is due in part to gas transport and the ability for the etcher to present reactive etchant species at the base of the hole and to transport the by-products away.

FIG. 5 shows that at least a portion of the first main surface 20a surrounding the trenches 27 and the side surfaces and bottoms of the trenches 27 themselves are lined with a dielectric material 33. Preferably, the entire first main surface 20a and all of the trenches 27 are lined with the dielectric material 33. The dielectric material may be deposited using a low pressure (LP) chemical vapor deposition (CVD) Tetraethylorthosilicate (TEOS) or a spun-on-glass (SOG) deposition technique or any other oxide deposition technique as is known in the art. In the preferred embodiments, the dielectric material is an oxide material but other dielectric materials could be used if desired.

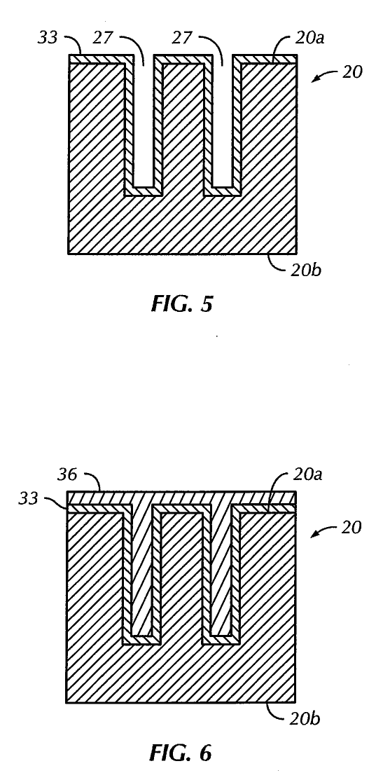

FIG. 6 shows that the trenches 27 are then filled with a conductive material 36 such as undoped polysilicon (poly), doped poly or a metal. Preferably, the trenches 27 are completely filled using a highly doped poly so that the resulting path defined by the fill material is highly conductive. There is a minimum deposition of conductive material 36 required to achieve a specified via resistance rating. As mentioned above, the poly may be N doped or P doped. Further, the poly may be deposited as in-situ doped poly or may be deposited as undoped poly and subsequently diffused with Phosphorous or Boron to achieve a high conductivity in the poly.

The amount of conductive material 36 required to fill the trenches 27 of FIGS. 3 and 3A is another important commercial parameter in the manufacture of semiconductors having through-wafer conductive vias. The amount of conductive material 36 required to refill the trenches 27 is, like the etch time discussed previously, directly proportional to the cost of manufacture of the semiconductor device that has the through-wafer conductive via. Therefore, the less the amount of conductive refill 36 required to fill the trenches 27, the lower the manufacturing cost of the semiconductor containing the through-wafer conductive via. This presents another challenge in the manufacture of semiconductors having through-wafer conductive vias in that the amount of a minimum conductive fill material 36 required for a trench 27 is directly proportional to the geometry of the shape of the trench 27. For circular shaped trenches 27 like those of FIG. 4A and FIG. 4B, the minimum conductive fill material 36 required is factor of 1 multiplied by the radius R (1×R) of the circular via and that product is then multiplied by the number of circular trenches 27. Thus, the minimum amount of conductive fill 36 required for the single circular trench 27 of FIG. 4A (R=39 μm) is approximately 39 μm. The minimum amount of conductive fill 36 required for each of the five circular trenches 27 of FIG. 4B (R=17 μm) is approximately 17 μm, thereby requiring a minimum conductive fill material of 85 μm (5×17). For a rectangular shaped trench 27 like that of FIG. 4C, the minimum amount of conductive fill 36 is a factor of 0.5 multiplied by the minimum dimension (length or width) of the rectangular via and that product then multiplied by the number of rectangular trenches 27. Thus, the minimum amount of conductive fill 36 required for the single rectangular trench 27 of FIG. 4C (L=240, A=20) is approximately 10 μm (0.5×20, with the width A being less than the length L). As the minimum amounts of conductive fill material 36 for the via shapes of FIGS. 4A and 4C show, the rectangular shaped via requires substantially less minimum conductive fill material 36 than that of the circular shaped vias of the same cross-sectional area.

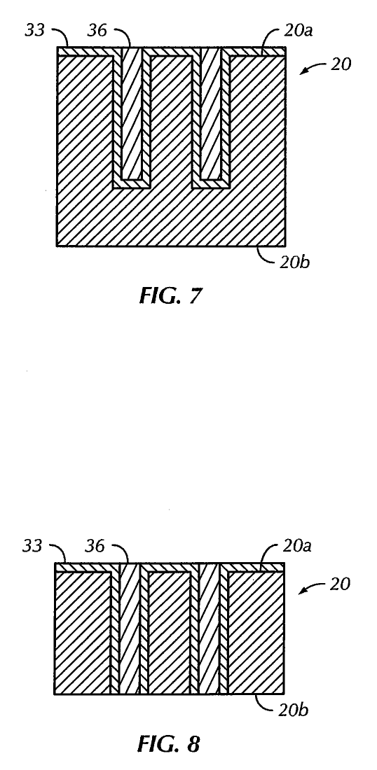

FIG. 7 shows the semiconductor substrate 20 after the first surface 20a has been planarized to expose the dielectric material 33 surrounding the trenches 27. The planarizing may be performed using chemical mechanical polishing (CMP) or any other suitable planarization technique. The amount of conductive material 36 that is lost when the first surface 20a is planarized is not a factor in the amount of conductive material 36 that is used to fill the trenches 27.

FIG. 8 shows the semiconductor substrate 20 after the second surface 20b has been planarized using a similar technique to expose the conductive material 36 at the second main surface 20b. The planarization of the second main surface 20b may be left for planarization by an intermediate manufacturer after other processing has been completed. For example, the base substrate 20 having conductive material 36 that forms conductive vias may be provided to an intermediate manufacturer for addition of an electrical component 90 and cap 80 prior to packaging the fabricated device.

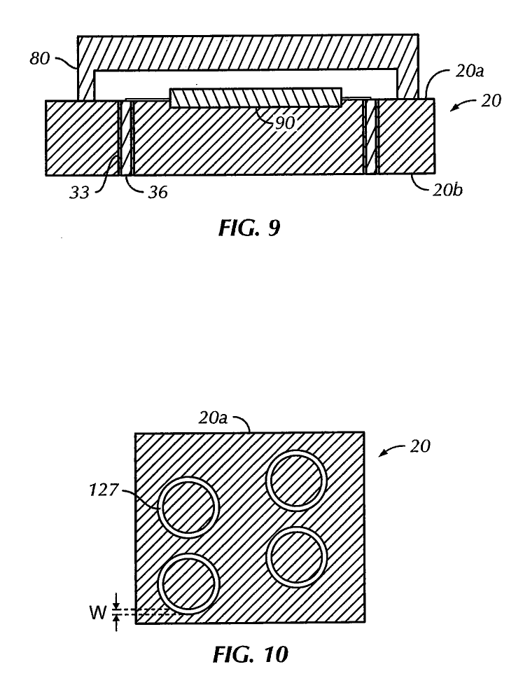

FIG. 9 shows that an electrical component 90 has been mounted to the first surface 20a of the semiconductor substrate 20 and that the electrical component 90 has been electrically connected to the conductive material 36 exposed at the first main surface 20a. The electrical component 90 may be a sensor device such as an accelerometer, a gyroscope, a rate sensor, a pressure sensor, a resonator, a temperature sensor and an optical sensor or any other sensor or device. The electrical component 90 may be any technology that requires mounting on a silicon substrate as would be known in the art. A cap 80 has been mounted to the first surface 20a of the silicon substrate so as to enclose at least a portion of the electrical component 90 and the electrical connections between the electrical component 90 and the conductive material 36. The cap 80 may be silicon, polymeric, ceramic, glass, metal and the like or any other suitable material. Preferably, the cap 80 completely encloses the electrical component 90 and the electrical connections between the electrical component 90 and the conductive material 36. The cap 80 may be bonded to the silicon substrate 20 using either direct wafer bonding or anodic bonding in order to provide a tight seal.

FIG. 9 shows a semiconductor device including the semiconductor substrate 20, at least one conductive via 36 extending from the first main surface 20a through the semiconductor substrate 20 to the second main surface 20b and a dielectric lining 33 surrounding the at least one conductive via 36 through the semiconductor substrate 20. The conductive via 36 is electrically isolated from the semiconductor substrate 20 by the dielectric liner 33. The electrical component 90 is electrically connected to the conductive via 36 at the first main surface 20a. The cap 80 is sealed to the first main surface 20a and encloses at least a portion of the electrical component 90 and the electrical connection between the electrical component 90 and the conductive via 36.

Preferably, the electrical component 90, such as a MEMS sensor, is completely contained within the cap 80 and the cap 80 is tightly sealed to the first main surface 20a. All interconnects to the electrical component 90 are made within or underneath the cap 80. The technique is suitable for use with silicon, polymeric, ceramic, glass or metal capping techniques and their equivalents.

The base substrate 20 can be fabricated with the through-wafer conductive vias 36 that are isolated from the substrate by dielectric liner 33 and then shipped to an intermediate manufacturer to add the electrical component 90 and metallization for leads. For example, an intermediate manufacturer may add the electrical component 90 and make electrical connections to the conductive vias 36 and then seal the cap 80 over the semiconductor substrate 20. The intermediate manufacturer can then planarize the second surface 20b of the substrate 20 and provide metallization for electrical connections and/or further packaging such as solder bumps or surface mount connections as is known in the art.

FIGS. 10-14 generally show a process for manufacturing a semiconductor device in accordance with a second preferred embodiment of the present invention.

Referring to FIG. 10, there is shown a partial sectional top plan view of a semiconductor substrate 20 having circular or annular trenches 127 etched therein. Similar to the first preferred embodiment, the trenches 127 extend at least to a first depth position D in the semiconductor substrate 20. The trenches 127 define a “perimeter boundary” around a portion of the semiconductor substrate 20. The portion of the semiconductor substrate bounded by the trenches 127 form conductive vias 142, 152 (FIG. 14). The perimeter boundary may be circular, triangular, rectangular, elliptical, polygonal or may be any non-geometric or geometric and symmetric or asymmetric shape.

The width W of the trench 127 generally depends on the overall thickness T of the silicon substrate 20, the depth D of the trench 127 and a desired aspect ratio of the depth D versus the width W. It is desirable to minimize the width W of the trench 127 so that any fill material can be minimized. However, the width W needs to be a certain minimum width to achieve the depth D of the trench 127 that is desired. Furthermore, the width W is also selected based upon the amount of electrical isolation that is required between the conductive vias 142, 152 and the rest of the silicon substrate 20.

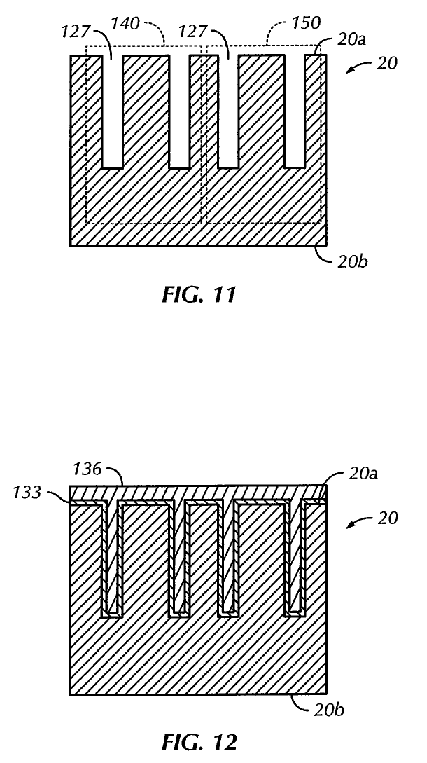

FIG. 11 shows a partial sectional side elevational view of the silicon substrate 20 having two annular trenches 127. Each trench 127 can be used to form a separate electrical via 142 isolated from another electrical via 152 (FIG. 14). In this case, area 140 encompasses a first via 142 and area 150 encompasses a second via 152 formed in the same silicon substrate 20. Of course, any number of vias 142, 152 may be formed in a silicon substrate 20 depending on the overall size of the silicon substrate 20, the width W of the trenches 127 and the overall size of each conductive vias 142, 152.

FIG. 12 shows the silicon substrate 20 after a dielectric lining 133 has been applied to at least a portion of the first main surface 20a surrounding at least the trenches 127. The dielectric material 133 also lines the sidewalls and bottoms of the trenches 127. Further, the trenches 127 have been filled with one of an insulating material and a semi-insulating material 136. The fill material may be undoped poly, doped poly, doped oxide, undoped oxide, silicon nitride or semi-insulating polycrystalline silicon (SIPOS) or some other suitably insulating or semi-insulating material.

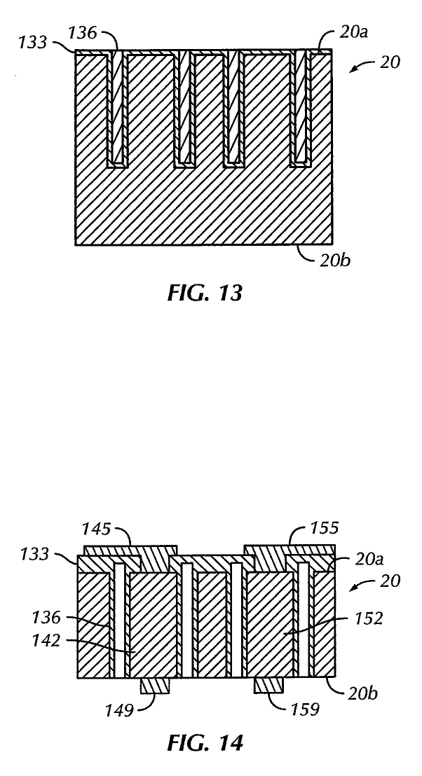

FIG. 13 shows the silicon substrate 20 after the first surface 20a has been planarized by using, for example, CMP.

FIG. 14 shows the semiconductor substrate 20 after contact windows have been opened up above conductive vias 142, 152 and metallization has been provided to form contacts at each end of the conductive vias 142, 152. For example, a metal contact 145 is formed at the first surface 20a of the silicon substrate 20 and is electrically coupled with the conductive via 142. Likewise, a metal contact 149 is disposed at the second surface 20b of the silicon substrate 20 after the second surface 20b has been planarized and is electrically coupled with the conductive via 142. Similarly, a metal contact 155 is formed at the first surface 20a of the silicon substrate 20 and is electrically coupled with the conductive via 152. Also, a metal contact 159 has been formed at the second surface 20b and is electrically coupled with the conductive via 152. An electrical component 90 can then be mounted in electrical connection with the contacts 145, 155 and a cap 80 can be sealed to the first main surface 20a of the silicon substrate 20 as described above in the first preferred embodiment. The contacts 149, 159 may be bumps as used in surface mount technology.

Alternatively, the conductive vias 142, 152 may be partially doped with one of Boron and Phosphorous or some other dopant. Likewise, the silicon substrate 20 may be doped or heavily doped prior to forming the trenches 127.

Other processing steps, as is known in the art, may be utilized without departing from the invention. For example, the trenches 27, 127 may be smoothed, if needed, using processing steps such as isotropic plasma etch or MEMS machining. Portions of the silicon substrate 20 or the entire device may have a sacrificial silicon dioxide layer grown thereon prior and then may be etched using a buffered oxide etch or a diluted hydrofluoric (HF) acid etch or the like to produce smooth surfaces and/or rounded comers thereby reducing residual stress and unwanted contaminants. Furthermore, additional insulation layers in addition to the dielectric layer may be added as desired. Furthermore, the conductive silicon substrate can be implanted and diff-used to achieve a particular conductivity.

From the foregoing, it can be seen that embodiments of the present invention are directed to a semiconductor device and methods for manufacturing a semiconductor device. Moreover, it can be seen that embodiments of the present invention are directed to a semiconductor device having through-wafer conductive vias and methods for manufacturing a semiconductor device having through-wafer conductive vias. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method of manufacturing a semiconductor device comprising:
providing a semiconductor substrate having first and second main surfaces opposite to each other;
forming in the semiconductor substrate at least one trench of a predetermined geometric shape in the first main surface, the at least one trench extending to a first depth position D in the semiconductor substrate;
lining the at least one trench with a dielectric material;
filling the at least one trench with a conductive material;
electrically connecting an electrical component to the conductive material of the at least one trench at the first main surface; and
mounting a cap to the first main surface, the cap enclosing at least a portion of the electrical component and the electrical connection between the electrical component and the conductive material.

2. The method according to claim 1, further comprising:
planarizing the first main surface to expose the dielectric material surrounding the at least one trench.

3. The method according to claim 2, wherein
the planarizing is performed by chemical mechanical polishing (CMP).

4. The method according to claim 1, wherein
the filling of the at least one trench is with at least one of undoped polysilicon, doped polysilicon and a metal.

5. The method according to claim 1, wherein
the at least one trench is formed utilizing micro-electro-mechanical systems (MEMS) technology to machine the semiconductor substrate.

6. The method according to claim 1, wherein
the at least one trench is formed utilizing one of reactive ion etching (RIE) and inductively coupled plasma deep reactive ion etching (ICP DRIE).

7. The method according to claim 1, wherein
the dielectric material is deposited using one of low pressure (LP) chemical vapor deposition (CVD) Tetraethylorthosilicate (TEOS) and a spun-on-glass (SOG) deposition.

8. The method according to claim 1, wherein
the electrical component is at least one of an accelerometer, a gyroscope, a rate sensor, a pressure sensor, a resonator, a temperature sensor, and an optical sensor.

9. The method according to claim 1, wherein
the predetermined geometric shape of the at least one trench is one of a substantially circular shape and a substantially rectangular shape.

10. The method according to claim 1, further comprising:
lining at least a portion of the first main surface surrounding the at least one trench with the dielectric material.

11. The method according to claim 1, further comprising:
planarizing the second main surface to expose the conductive material at the second main surface.

12. A method of manufacturing a semiconductor having a conductive via comprising:
providing a semiconductor substrate having first and second main surfaces opposite to each other;
forming in the semiconductor substrate at least one trench of a substantially rectangular shape in the first main surface, the at least one trench extending to a first depth position D in the semiconductor substrate;
lining the at least one trench with a dielectric material;
filling the at least one trench with a conductive material; and
planarizing the second main surface to expose the conductive material surrounding the at least one trench, the at least one trench forming the conductive via.

13. The method according to claim 12, further comprising:
planarizing the first main surface to expose the dielectric material surrounding the at least one trench.

14. The method according to claim 13, wherein
the planarizing is performed by chemical mechanical polishing (CMP).

15. The method according to claim 12, wherein
the planarizing is performed by chemical mechanical polishing (CMP).

16. The method according to claim 12, wherein
the at least one trench is formed utilizing one of reactive ion etching (RIE) and inductively coupled plasma deep reactive ion etching (ICP DRIE).

17. A method of manufacturing a semiconductor device comprising:
providing a semiconductor substrate having first and second main surfaces opposite to each other;
forming in the semiconductor substrate at least one trench of a predetermined geometric shape in the first main surface, the at least one trench extending to a first depth position D in the semiconductor substrate;
lining the at least one trench with a dielectric material; and
filling the at least one trench with a conductive material.

18. The method according to claim 17, wherein
the predetermined geometric shape of the at least one trench is one of a substantially circular shape and a substantially rectangular shape.
